(19) United States
(12) Patent Application Publication
(10) Pub. No.: US 2008/0204966 A1
(43) Pub. Date: Aug. 28, 2008

(54) Controlled Transport and Assembly of Nanostructures

(75) Inventors: Donglei Fan, Baltimore, MD (US); Frank Q. Zhu, Baltimore, MD (US); Chia-Ling Chien, Cockeysville, MD (US); Robert C. Cammarata, Columbia, MD (US)

Correspondence Address: EDWARDS ANGELL PALMER & DODGE LLP, P.O. BOX 55874, BOSTON, MA, 02205, US

(73) Assignee: THE JOHNS HOPKINS UNIVERSITY, BALTIMORE, MD (US)

(21) Appl. No.: 11/663,488

(22) PCT Filed: Sep. 21, 2005
(86) PCT No.: PCT/US2005/033972

§ 371 Date: Dec. 17, 2007

Related U.S. Application Data
(60) Provisional application No. 60/611,748, filed on Sep. 21, 2004.

(51) Int. Cl. H02N 11/00

(52) U.S. Cl. 361/233; 977/882

(57) ABSTRACT

Systems and methods for manipulating nanostructures, such as nanospheres, nanodisks, nanowires, and nanotubes. The systems and methods permit the construction of nano-scale contacts, scaffolds, and motors using electric fields that do not require the use of toxic nanostructure materials. The electric fields are imposed on the nanostructures using electrodes having specific shapes and driven with voltages having particular amplitudes, frequencies, and phase differences. The electrode shape and voltage characteristics influence the configuration of the electric fields, which in turn influences the ultimate configuration of the nanostructures. The nanostructures retain their configuration after the electric fields and any transport medium, such as deionized water, are removed.

### CROSS REFERENCE TO RELATED APPLICATION

This application claims the benefit of, and incorporates herein in its entirety by reference, U.S. Provisional Application No. 60/611,748, filed Sep. 21, 2004.

### STATEMENT REGARDING FEDERALLY SPONSORED RESEARCH OR DEVELOPMENT

The U.S. Government has a paid-up license in this invention and the right in limited circumstances to require the patent owner to license others on reasonable terms as provided for by the terms of contract DMR0080031 awarded by the National Science Foundation.

### TECHNICAL FIELD

The present invention relates generally to nanostructures and, more specifically, to systems and methods of manipulating nanostructures to create nano-scale contacts, scaffolds, and motors.

### BACKGROUND INFORMATION

A variety of small entities of low dimensionalities, such as nanospheres, nanodisks, nanowires, and nanotubes, have recently been extensively explored due to their unique attributes and capabilities to bind chemical and biological entities of interest. Nanowires are one type of small entities with a large aspect ratio. Their geometrical shape and the multifunctionalities realized in multi-component nanowires allow tuning of their physical, chemical, and electrical properties. For example, nanowires have been explored as chemical and biological sensors, nano-lasers. Multilayered nanowires have been proposed as barcode in bio assay, and gene therapy vessels. Chemical and biological entities, even living cells, have been successfully attached to nanowires.

These attributes notwithstanding, nanowires often need to be transported and assembled in suspension in order to exploit and capture their unique properties. To date, nanowires containing magnetic segments have been manipulated to some degree by applying external magnetic fields using electromagnets or permanent magnets over centimeter length scale. The toxicity of magnetic metals such as nickel and cobalt to living systems such as cells, limits the application of magnetic nanowires in biological systems.

From the foregoing, it is apparent that there is a need to manipulate nanostructures, such as nanowires, not containing toxic elements using a mechanism other than a magnetic field.

### SUMMARY OF THE INVENTION

The present invention provides systems and methods to transport and assemble nanostructures. In comparison to systems presently in use, apparatus and methods according to the invention provide efficient transport and assembly using easily generated fields that do not require the use of toxic nanostructure materials.

With the application of AC electric fields with a suitable choice of suspension fluid and electrode geometries, metallic nanostructures (e.g., nanowires), regardless of being magnetic or non-magnetic, can be driven efficiently to align, to chain, to accelerate in directions parallel or perpendicular to the orientation of the electric field, to concentrate and assemble onto designated places, and to disperse on a microscopic scale. Furthermore, the nanowires can be compelled to rotate with high angular velocities with a specific chirality. A new type of micro-motor results from using the AC electric field on a single rotating nanowire.

To transport efficiently and rotate nanowires in suspension, one should first quantitatively characterize the force on metallic nanowires due to the AC electric field. This force is called the dielectrophoretic force (“DEP”), and the quantitative information permits the design of special electrodes to manipulate nanowires in suspension with high efficiencies despite very low Reynolds numbers.

The high polarizability of metallic nanowires and their large aspect ratio give rise to an enhancement of electrical polarization 380 times relative to that of nanospheres. The low conductivity of the deionized (“DI”) water further enhances the DEP effect. Consequently, large DEP forces result allowing the transport of nanowires to designated places for assembly in a direction either parallel or perpendicular to its orientation. Also, nanowires can be compelled to rotate with either chirality to at least 1800 rpm.

With properly designed electrodes (e.g., “micro-electrodes”), randomly oriented nanowires in suspension can be assembled into scaffolds. Nanowires can be constructed into two dimensional (2-D) and three dimensional (3-D) structures. By applying an AC electric field onto two electrodes of a suitable separation, nanowires suspended in DI water can be positioned into the electrode gap and make ohmic contact with the electrodes, thereby allowing for the incorporation of nanowires into a circuit.

Although the discussion above and examples below refer to nanowires, other nanostructures (e.g., nanospheres, nanodisks, and nanotubes) can be manipulated according to the invention. In some instances, elongated nanostructures (e.g., nanowires or carbon nanotubes) offer superior performance.

Other aspects and advantages of the present invention will become apparent from the following detailed description, taken in conjunction with the accompanying drawings, illustrating the principles of the invention by way of example only.

### BRIEF DESCRIPTION OF THE DRAWINGS

The foregoing and other objects, features, and advantages of the present invention, as well as the invention itself, will be more fully understood from the following description of various embodiments, when read together with the accompanying drawings, in which:

FIGS. 1A and 1B are schematic views depicting a system for transporting a nanostructure in accordance with an embodiment of the invention;

FIGS. 2A, 2B, and 2C are schematic views depicting electrode configurations in accordance with an embodiment of the invention;

FIGS. 3A, 3B, 3C, and 3D are schematic views depicting quadruple electrode configurations in accordance with an embodiment of the invention;

FIG. 4A is a schematic view depicting performance of a circular electrode in accordance with an embodiment of the invention;

FIGS. 4B and 4C are graphs depicting operational parameters of a circular electrode in accordance with an embodiment of the invention;

FIGS. 4D, 4E, 4F, 4G, 4H, and 41 are micrographs depicting transport of a nanostructure in accordance with an embodiment of the invention;

FIG. 5A is a schematic view depicting performance of a quadruple electrode in accordance with an embodiment of the invention;

FIGS. 5B, 5C, 5D, 5E, 5F, and 5G are micrographs depicting transport of a nanostructure in accordance with an embodiment of the invention;

FIGS. 6A and 6B are micrographs depicting rotation of a nanostructure in accordance with an embodiment of the invention;

FIGS. 6C and 6D are graphs depicting operational parameters of a system for rotating a nanostructure in accordance with an embodiment of the invention;

FIG. 6E is a schematic view depicting a system for rotating a nanostructure in accordance with an embodiment of the invention;

FIGS. 6F, 6G, 6H, and 6I are micrographs depicting rotation of a nanostructure in accordance with an embodiment of the invention;

FIG. 7A is a micrograph depicting a nanostructure contact in accordance with an embodiment of the invention;

FIG. 7B is a graph depicting operational parameters of a nanostructure contact in accordance with an embodiment of the invention;

FIGS. 8A, 8B, and 8C are micrographs depicting a nanostructure scaffold in accordance with an embodiment of the invention;

FIGS. 9A, 9B, and 9C are micrographs depicting a nanostructure scaffold in accordance with an embodiment of the invention; and

FIGS. 10A, 10B, and 10C are micrographs depicting a nanostructure scaffold in accordance with an embodiment of the invention.

### DESCRIPTION

As shown in the drawings for the purposes of illustration, the invention can be embodied in systems and methods for transporting and assembling nanostructures. Embodiments of the invention are useful for creating nano-scale contacts, scaffolds, and motors.

The physics of embodiments of the invention relates to the interaction between the polarized charges on the small entities in suspension and the applied electric field, as effect known as DEP. The technique of DEP has been used as a biological cell separation technique, to align and chain nanowires for electrical measurement, and to separate semiconductive carbon nanotubes from the insulating ones with some degree of success. Embodiments of the invention include electrodes designed with specific geometries to achieve far greater DEP force than before.

The motion of particles in suspension in response to applied AC electric field is due to the Coulomb interaction between the electric field and the electrically polarized nanowires. If a particle is more polarized than its surrounding media, the coulomb interaction will attract it towards the higher electrical field, the positive DEP. If the particle is less polarized than its surrounding media, it will be repelled to the lower electrical field, the negative DEP.

The DEP force depends on the polarization of the particle and the gradient of the electric field, and is expressed as (p_{eff}· V̅)E, where E is the time dependent electric field and p_{eff} is the instantaneous effective polarization of the particle, which is proportional to E. Both E and p_{eff} are typically time dependent vector quantities.

The motion of nanowire of length L and radius a_{NW} in a fluid by an external force F is governed by ma=F−bv, where a and v are respectively the acceleration and velocity of the nanowire. The last term is the drag force due to viscosity with b=3πηLD, where η is the viscosity, D is the shape factor, which for a nanowire of an aspect ratio of 33 is 0.18. For a constant F including no force, the motion of the nanowire is dictated by m/b≈2a_{NW}²ρ_{Au/η, where ρ}_{Au} is the density of the gold. For a ten micron gold nanowire of a radius of a_{NW}=0.15 μm, m/b is only approximately 10⁻⁶ S. In the absence of external force, a nanowire with an initial velocity of vᵢ=100 μm/s will be stopped within a short distance of vᵢm/b≈1 Å in about 10⁻⁶ s. This illustrates the fundamental difficulty of moving small entities in suspension with extremely small Reynolds numbers of about 10⁻⁵. A small Reynolds number dictates that the drag force due to viscosity will overwhelm the motion of the entity. To transport nanowires efficiently in suspension, one needs not only a large force but also a force that increases in magnitude. The AC-driven DEP force with specially designed electrodes meets these requirements.

The theory of DEP is based on the polarization of dielectric materials (such as polymeric particles and cells) under an external electric field. The DEP effect on metallic entities has been much less explored. The theory for DEP on dielectrics can be extended for metallic entities, in particular, spheres in a medium. Both the metallic entities and the medium in which the entities are embedded contribute to the DEP effect. Our calculation shows that metallic nanowires (10 micron length, 0.3 micron diameter), in comparison with spherical metallic particles, enhance the electrical polarization by a factor of 380 due to its high aspect ratio. The very low conductivity of 2.4 μSiemens/cm of the DI water also enhances the DEP effect. These two factors result in a large acceleration that accommodates the efficient manipulation of metallic nanowires in low Reynolds number flow (approximately 1×10⁻⁵ in DI water).

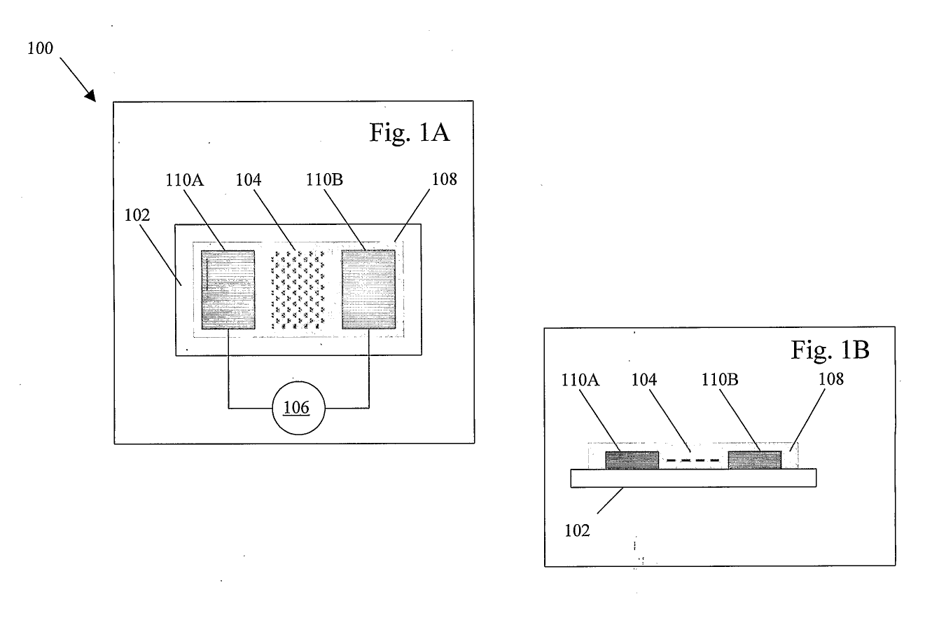

In brief overview, FIG. 1A is a schematic view depicting a system 100 for transporting a nanostructure in accordance with an embodiment of the invention. Transporting refers to manipulating the nanostructure such that the center of mass of the nanostructure moves over a long range (i.e., a distance much larger than any dimension of the nanostructure). This is distinguishable from alignment, where only small movements (e.g., pivoting) occur, typically without any movement of the center of mass.

Typical nanostructures include nanospheres, nanodisks, nanowires, and nanotubes. These nanostructures can be characterized by an aspect ratio, which is the ratio of the length of the nanostructure to its width. For some nanostructures, such as nanowires and nanotubes, the aspect ratio has a value greater than one. For example, in some embodiments, nanowires are about ten to fifteen microns long, and have a diameter of about 0.3 micron. Consequently, their aspect ratio (length divided by diameter) is greater than about thirty. Nanowires can be fabricated from, for example, gold using electrodeposition through a nanoporous template from gold plating solution (e.g., Orotemp24, manufactured by Technic Inc.) with a plating voltage of −1V with respect to the standard silver/silver chloride reference electrode. The gold nanowires are suitable because gold is conducting, non-magnetic, chemically inert, and adaptable to thiol-chemistry functionalization for bio-patterning and bimolecular detection.

The system 100 includes a substrate 102 made of, for example, quartz, that supports the nanostructure 104. A transport medium 108 surrounds the nanostructure 104. In general, the transport medium 108 can be any nonconductive liquid, such as DI water. A typical conductivity is 2.4 μSiemens/cm. FIG. 1B depicts a side view of the system 100 where the nanostructure 104 is typically submerged in the transport medium 108.

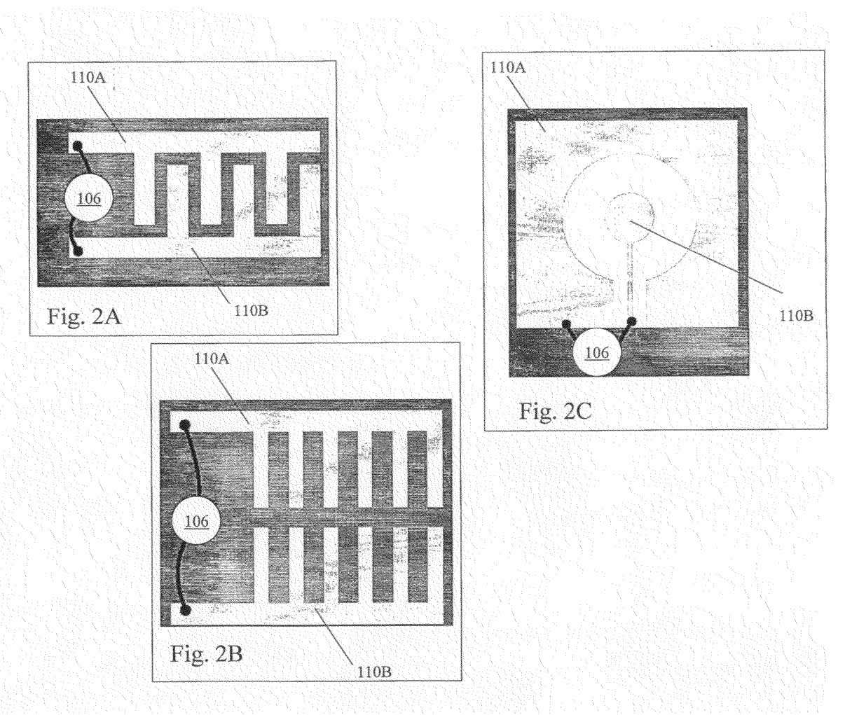

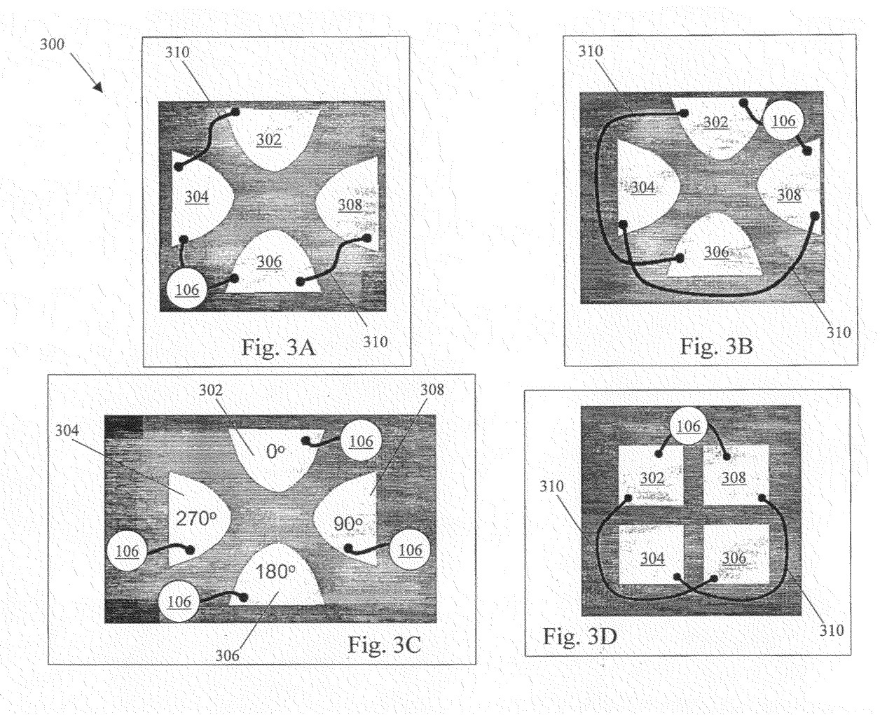

Two or more electrodes 110A, 110B (collectively, 110) are in contact with the transport medium 108 and are connected to a field generator 106. In some embodiments, the field generator 106 can generate an electric field and an electric field gradient in the transport medium 108 that affects the motion of the nanostructure 104. The configuration of the electric field and the electric field gradient is related to the number and geometry (e.g., shape) of the electrodes 110. (The electrodes are generally patterned by laser micromachining on the substrate.) For example, FIGS. 2A and 2B depict parallel (i.e., interdigitated) and bipolar electrodes, respectively. The electric field and the electric field gradient produced by these electrode configurations is generally different from that produced by the circular electrodes depicted in FIG. 2C. As depicted in FIG. 3A, some embodiments use quadruple electrodes 302, 304, 306, 308 (collectively, 300) for more variation in the configuration of the electric field and the electric field gradient. Changing interconnections between the electrodes 300 changes the configuration of the electric field and the electric field gradient as well. Compare, for example, the differing interconnections 310 shown in FIGS. 3A and 3B.

In embodiments where the electric field is time varying (i.e., an AC field), phase differences between parts of the field emanating from each of the electrodes 302, 304, 306, 308 as depicted in FIG. 3C can change the configuration of the electric field and the electric field gradient. Further, some embodiments use square electrodes as depicted in FIG. 3D for different field configurations. In the embodiments of the invention, the type, number, and geometry of the electrodes used depends at least in part on the desired final orientation of the nanostructures 104. The nanostructures 104 will adopt an orientation with reference to the electric field, or the electric field gradient, or both. Once an orientation is chosen, electrodes providing a field or field gradient pattern corresponding to the orientation are selected, interconnected, and energized as needed.

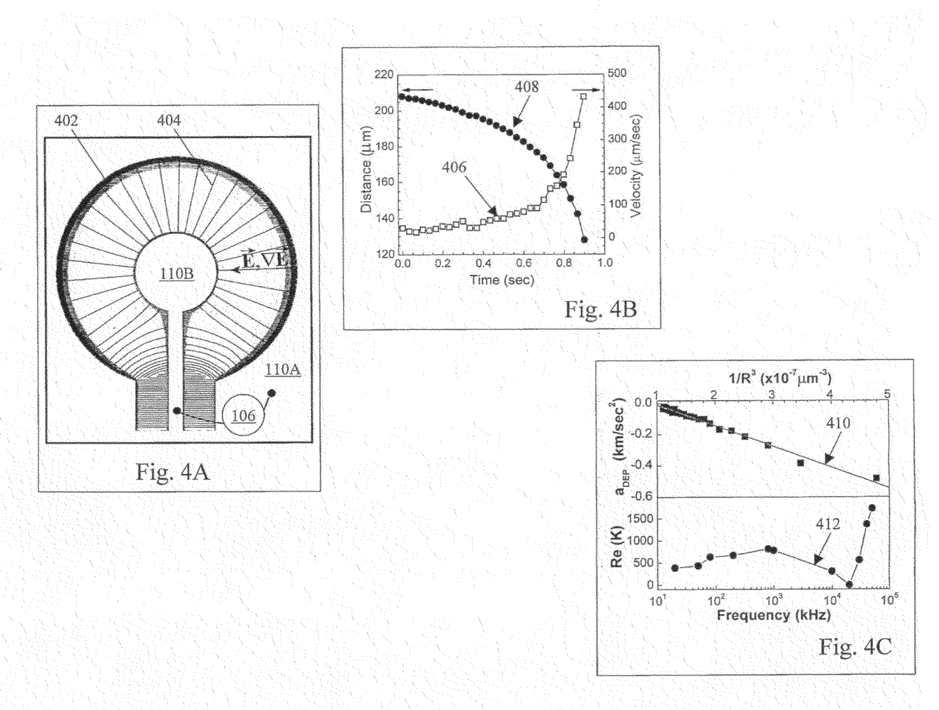

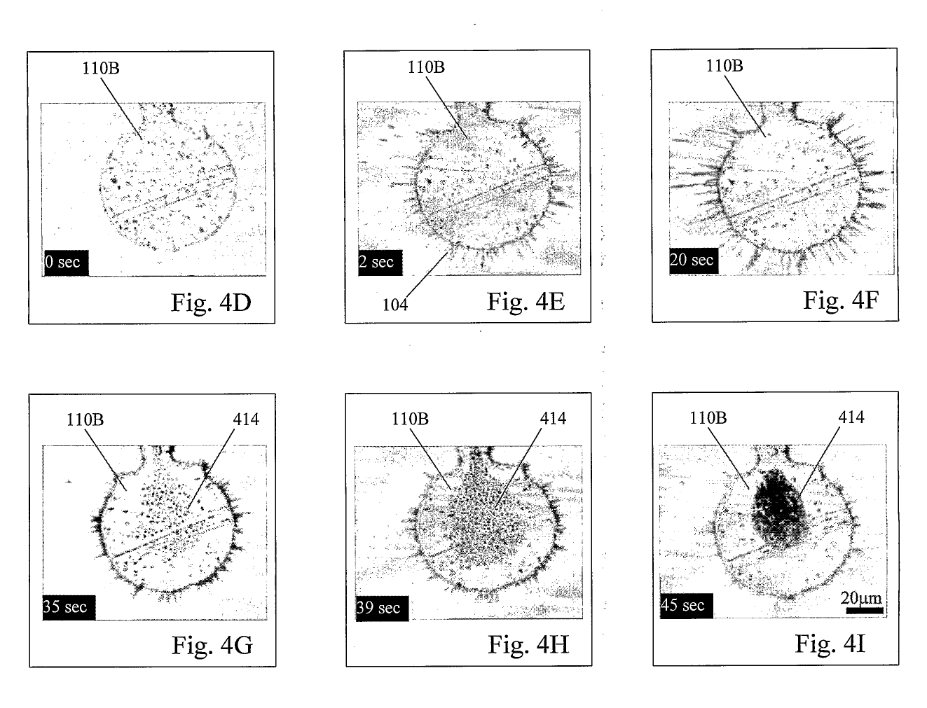

Some embodiments use a pair of circular electrodes 110A, 110B as depicted in FIG. 4A. When the field generator 106 (e.g., a voltage source) energizes the electrodes 110A, 110B, a series of equipotential surfaces 402 forms in the gap between the electrodes 110A, 110B. Field lines 404 represent the corresponding electric field. For this electrode configuration, the associated electric field gradient is in the same direction as the electric field.

By way of example, with circular electrodes 110A, 110B having inner and outer radii of 70 microns and 270 microns, respectively, both the electric field and its gradient are along the radial direction with known dependences of 1/r and 1/r² respectively, where r is the distance from the center of the circles. The calculated electric field between the electrodes, as shown in FIG. 4A, illustrates that the circular symmetry between the electrodes is largely maintained except near the openings of the electrodes. Under an AC voltage with a frequency greater than about 10 kHz, the nanostructures 104 (e.g., nanowires) align radially and accelerate until they are attached and chained to the inner electrode 110B.

In circularly concentric electrodes, the DEP force on nanowires in DI water is expressed as (p_{eff}· V̅)E, which is along the radial direction with the magnitude of

$${F}_{DEP} = \frac{{V}_{rms}^{2}}{{( ln \frac{{r}_{2}}{{r}_{1}} )}^{2}} {V}_{NW} {ɛ}_{m} Re ( K ) \frac{1}{{r}^{3}}$$

where p_{eff} is the polarization of the nanowires and is proportional to E, Vᵣₘₛ the root-mean squared value of the applied AC voltage, r₁ and r₂ the radii of the electrodes, V_{NW} the volume of the nanowires, ∈ₘ=80 (the dielectric constant of the fluid), r is the distance between the nanowire and the center of the circular electrode, and Re(K) is the real-part of the Clausius-Mossotti factor, which includes the enhancement factor of 380.

Using the circular electrodes 110A, 110B, the motion of an individual nanowire can be captured using a video camera by measuring the displacement vs. time. Doing so allows the collection of distance data 408 as shown in FIG. 4B. From the distance data 408 (acquired with a 10V, 40 MHz bias applied to the electrodes 110A, 110B) the velocity 406 and acceleration can be computed by differentiation. For example, using the distance data 408, a nanowire traverses 80 microns in 0.9 s, and acquires a final velocity of 0.43 mm/s and acceleration of 3 mm/s² before it reaches the inner electrode 110B. These are high values for the motion of a small entity, demonstrating that an AC electric field having a frequency from about 10 kHz to about 50 MHz is generally more effective for transporting nanostructures compared to a magnetic field.

The values of FDEP can be determined from the equation above using the value bv=3πηLDv for the drag force due to viscosity described above. FIG. 4C depicts the value 410 of a_{DEP}=FDEP/m is plotted as a function of 1/r³. The linear relation confirms the predicted 1/r³ dependence shown in the equation above. Note that at 40 MHz (with V_{AC}=10V), a_{DEP} as much as about 0.5 km/s², five orders of magnitude higher than the actual acceleration, has been achieved by the AC electric field alone. Nevertheless, this large acceleration is reduced because of the large drag force, which is a result when the transport medium 108 has a small Reynolds number (e.g., less than or equal to about 1×10⁻⁵). Note that the Reynolds number is not a fixed value, because it depends on the speed of the entity. A Reynolds number of 1×10⁻⁵ is for a typical length nanowire moving at a typical speed. An actual Reynolds number of a nanowire can be larger or smaller than this, but will generally be in a close order of magnitude.

Using the slope of the plotted value 410 and the equation above, values of Re(K) can be determined. Re(K) is generally not a constant but depends on frequency. As depicted in FIG. 4C, the value of Re(K) 412 shows a maximum of 781 at 1 MHz, and reduces to about zero at 20 MHz before increasing rapidly to 1733 at 50 MHz. This frequency dependence is generally due to the conductivity and permittivity of the transport medium 108 and the nanowire. Consequently, the polarizability of the nanowires in the transport medium 108 is typically frequency dependent. The small measured value of Re(K) near 20 MHz may be due to circuit absorption. The strong frequency dependence can also be exploited to separate materials with different AC characteristics.

In some embodiments, the circular electrodes 110A, 110B assist with the movement of nanospheres. For example, gold spheres 104 (with radii from about two microns to about eight microns) suspended in DI water and exposed to an 80 MHz, 10V signal can be chained, accelerated, and attached at various locations onto the inner electrode on the circumference of the circular electrode 110B as shown in FIGS. 4D through 4F. Gold spheres 104 can also be transported to the top of the circular electrode 110B when the frequency is reduced from 10 kHz to 1 kHz at 10V, as depicted in FIGS. 4D through 4F, which show an aggregation 414 of the gold spheres 104.

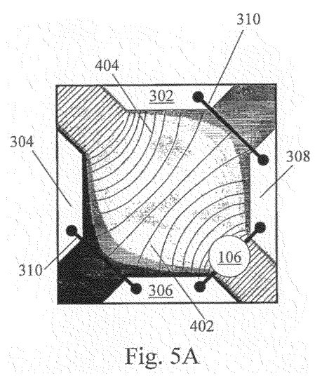

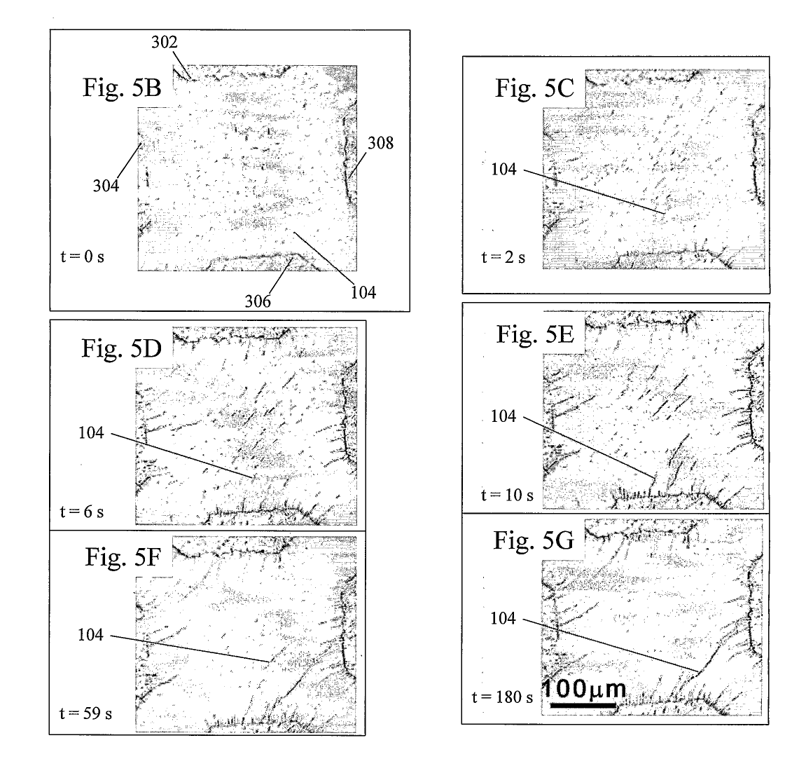

Other embodiments use the quadruple electrodes 300 as depicted in FIG. 5A. These electrodes also exhibit a series of equipotential surfaces 402 that forms in the gap between the electrodes. Field lines 404 represent the corresponding electric field. The location of the connections of the field generator 106 and the interconnections 310 influence the ultimate configuration of the electric field and the electric field gradient. In contrast to embodiments using the circular electrodes 110A, 110B, the quadruple electrodes 300 accelerate the nanostructures 104 (e.g., nanowires) in the direction perpendicular to their orientation, capitalizing on the fact that the alignment and the acceleration of the nanowires are along the electric field and its gradient direction, respectively. For the quadruple electrodes 300 depicted in FIG. 5A, the electrodes 300 on opposite sides are electrically connected and a voltage of ten volts at a frequency of one MHz was applied. The calculated electric field (shown by the lines 404) and the equipotential curves (shown by the contours 402) are also shown. Note that the electric field gradient is perpendicular to the electric field and be directed away from the center.

FIGS. 5B through 5G provide an example of nanostructure transport using the quadruple electrodes 300. Nanostructures 104 (e.g., nanowires) with random orientations are depicted in FIG. 5B. FIGS. 5C, 5D, 5E, and 5F depict the nanowires at two, six, ten, and fifty-nine seconds, respectively after the application of an AC voltage (10V, 1 MHz). The aligning of the nanowires along the electric field direction occurred essentially instantaneously (FIG. 5C), with significant chaining at six seconds (FIG. 5D). In this respect, the alignment of the nanowires reveals the actual electric field. Simultaneously, the nanowires were also being transported towards the high-field regions, moving perpendicular to the alignment direction and thus being depleted from the central region and to congregate at opposite gaps between the electrodes as shown in FIGS. 5E and 5F. The alignment and the assembly of nanowires clearly demonstrate the different roles of the electric field and its gradient. The nanowires are essentially completely depleted from the center and collected to the electrodes in three minutes (FIG. 5G). When the AC voltage is turned off at any time during this process, the nanowires immediately stop at their locations.

With this principle, nanostructures can be transported to designated places and assembled into all kinds of patterns with precise spatial control by the appropriately designed three dimensional electrodes.

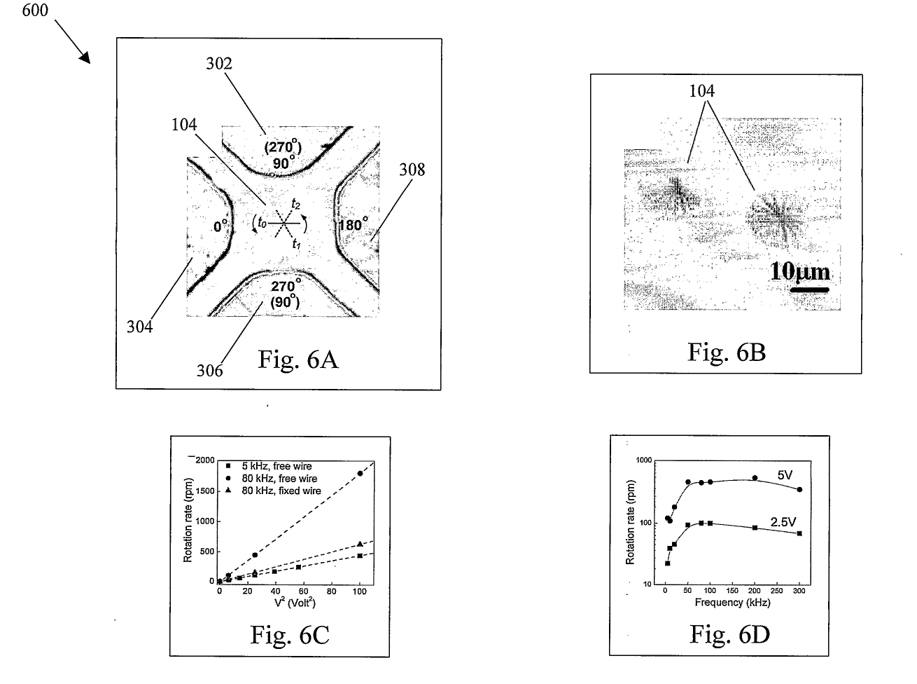

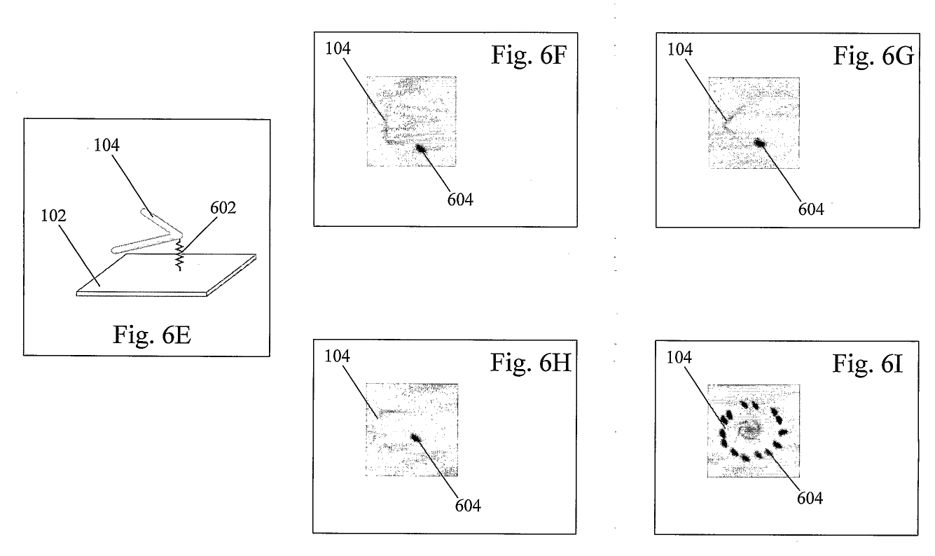

In brief overview, FIG. 6A depicts a system 600 for rotating a nanostructure 104 in accordance with an embodiment of the invention. In some embodiments, quadruple electrodes 302, 304, 306, 308 encircle the nanostructure 104. Typically, each of the quadruple electrodes 302, 304, 306, 308 is driven by a voltage source, with the voltage sources having the same magnitude and frequency, but having phase differences relative to each other. For example, FIG. 6A depicts a sequential phase shift of ninety degrees between each of the four quadruple electrodes 302, 304, 306, 308. These voltages create electric fields that cause rotation of the nanostructure 104 (e.g., a nanowire) placed in the central region between the quadruple electrodes 302, 304, 306, 308. The rotation rate of an individual nanowire can be determined by measuring the amount of rotation for a fixed time interval.

There is at least one location on the nanostructure 104 that is able to be, but need not be, attached to the substrate 102. That is, both free nanowires and nanowires with one end fixed to the substrate can be rotated. A nanowire with one end fixed rotates slower than the free nanowires as shown in FIG. 6B, which depicts sequential overlapped micrographs taken at an interval of approximately ⅓ second (i.e., nine frames taken at thirty frames per second) with the quadruple electrodes 302, 304, 306, 308 biased at 2.5V at 80 kHz.

The rotation rate of a nanowire depends on both the magnitude and the frequency of the applied AC voltage. The rotation rate for both free and fixed nanowires increases with voltage as V² as shown in FIG. 6C with slopes of 4.5 rpm/V² at 5 kHz, 18.1 rpm/V² at 80 kHz for free nanowires, and 6.3 rpm/V² at 80 kHz for fixed nanowires. The V² dependence is favorable for achieving high rates of rotation. For example, 1800 rpm is achievable with an AC voltage of 10V and frequency of 80 kHz. The rotation can be reduced to 445 rpm by changing the frequency to 5 kHz. FIG. 6D depicts the dependence of rotation rate on frequency where, at the voltages of 2.5 V and 5V, rotation rate increases sharply from 5 to 80 kHz before decreasing slowly from 80 kHz to 300 kHz.

One feature of rotation is its chirality, which in this case can be controlled by the phase of the AC voltages applied to the quadruple electrodes 302, 304, 306, 308. Using the geometry shown in FIG. 6A, the rotation chirality is always opposite to the phase shift direction; the rotation is clockwise (or counter-clockwise) when the phase shift was −90 degrees (or 90 degrees). This has been obtained in the frequency range of 5 kHz to 300 kHz studied. The above results show that both the rotation rate and the chirality of rotation can be precisely controlled by the magnitude, the frequency, and the phases of the AC voltages applied to the four electrodes.

FIG. 6E depicts a bond 602 (e.g., a chemical bond) between a kink of a bent nanostructure 104 (e.g., nanowire) and the substrate 102. An AC voltage of 10V and 20 kHz, is applied onto the quadruple electrodes 302, 304, 306, 308 with a sequential phase shift of ninety degrees between each. FIGS. 6F, 6G and 6H depict a dust particle 604 being whipped and driven by the two arms of the bent nanowire. The movement of the dust particle 604 under the thrash of nanowire is depicted clearly in FIG. 6I in the sequential overlapped micrographs taken over a period of 1.8 seconds (e.g., using a video camera having a frame rate of 30 frames per second), with an electrode bias of 10V at 20 kHz. Accordingly, nanowires can be used as micro-stirrers to alleviate the difficult problems of poor mixing in low Reynolds number flows as encountered in micro total analysis systems (“μTAS”).

In certain embodiments, a nanostructure 104 includes at least one location that can be attached to an adjacent member, such as an electrode or another nanostructure. To affect such contact, an electric field is imposed on the nanostructure 104 through the transport medium 108, thereby moving the nanostructure 104 into proximity with the adjacent member. When the transport medium 108 dissipates (e.g., evaporates or is otherwise removed), the contact remains substantially intact without the presence of an electric field or electric field gradient. In most instances, the resulting contact is ohmic.

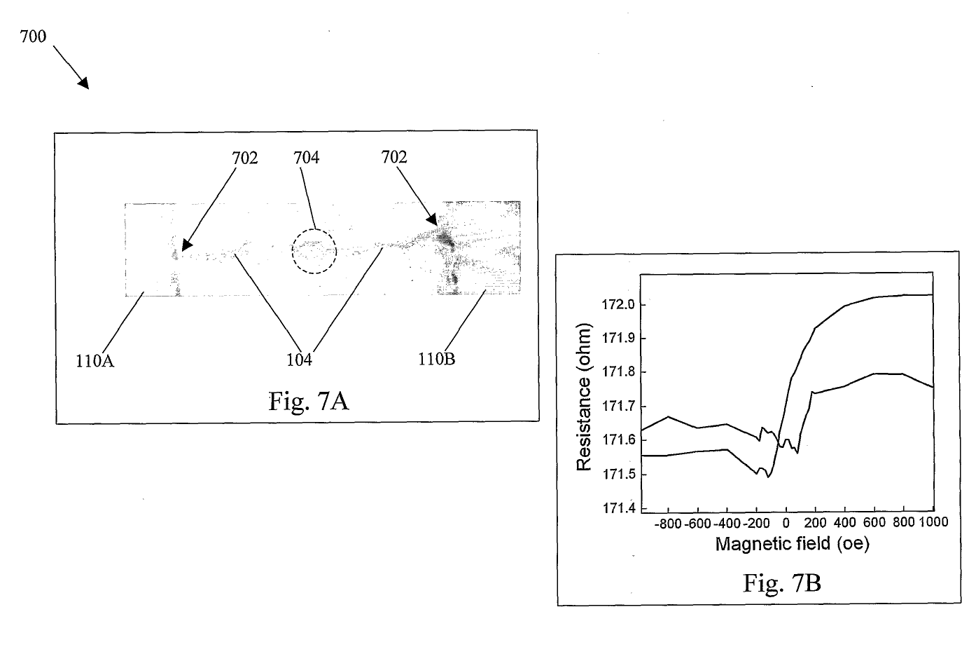

By way of example, FIG. 7A depicts the effect of applying an AC electric field at a frequency of 10 kHz to 50 MHz onto electrodes 110A, 110B. Nanostructures 104 (e.g., nanowires) suspended in DI water are attracted and positioned into the electrode gap and make ohmic contacts with the electrodes. This can be done with both single material (e.g., gold or nickel) and multilayered (e.g., three segment gold-nickel-gold) nanostructures 104. FIG. 7A depicts three segment gold-nickel-gold multilayered nanowires chained and trapped between two microelectrodes with a gap of 63.5 microns. After the DI water evaporates, the nanowires remain at their positions. The nanowires form ohmic contact with the electrodes. FIG. 7B depicts an anisotropic magnetic resistance (“AMR”) of these chained gold-nickel-gold multilayered nanowires at room temperature, with the nickel segment having a length of ⅓ of a nanowire. This, or a similar configuration, would allow nanowires to be incorporated into integrated circuits.

Randomly oriented nanostructures in suspension can be aligned and patterned into high-density arrays (e.g., scaffolds) according to the electric field distribution, which can be designed using electrodes of suitable geometrical shapes. (The particulars (e.g., amplitude, frequency, and phase) of the signals applied to the electrodes also influence the pattern.) Due to the electric field gradient, the nanostructures are transported and, due to the electric field, the nanostructures conform to (e.g., align with) the pattern. The polarizability of the nanostructures, the nanostructure material, and the type of transport medium 108 used influences whether the nanostructures are transported to one or more locations near the electrodes. After the transport medium 108 dissipates, the nanostructures remain substantially in the pattern. Consequently, a two or three dimensional scaffold is obtained.

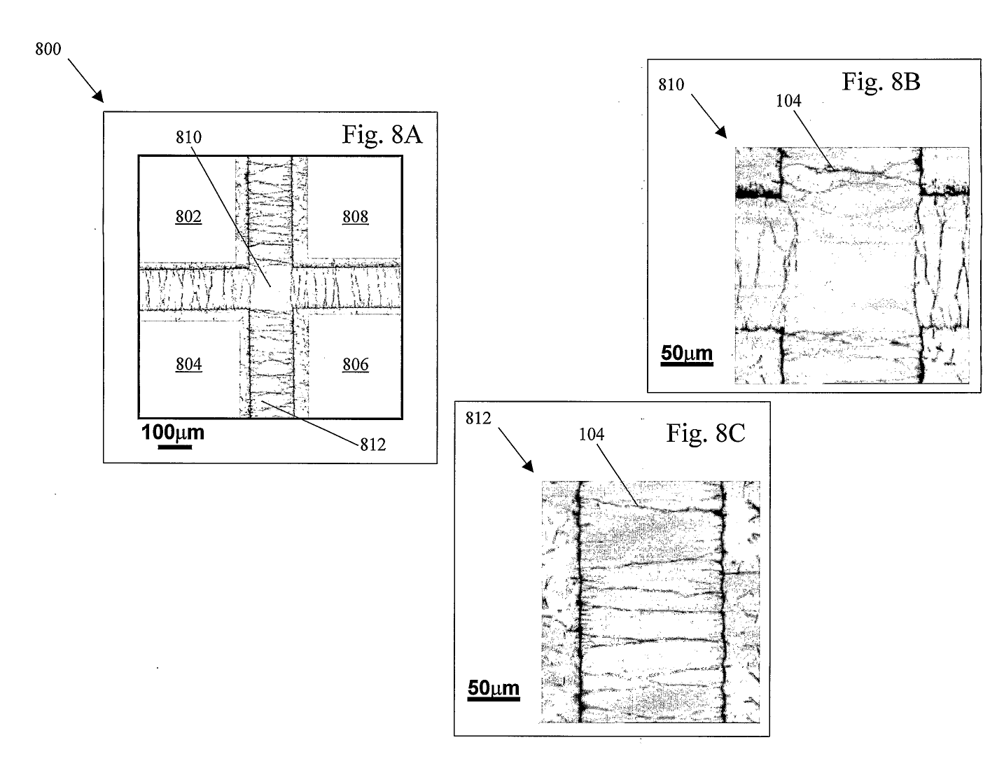

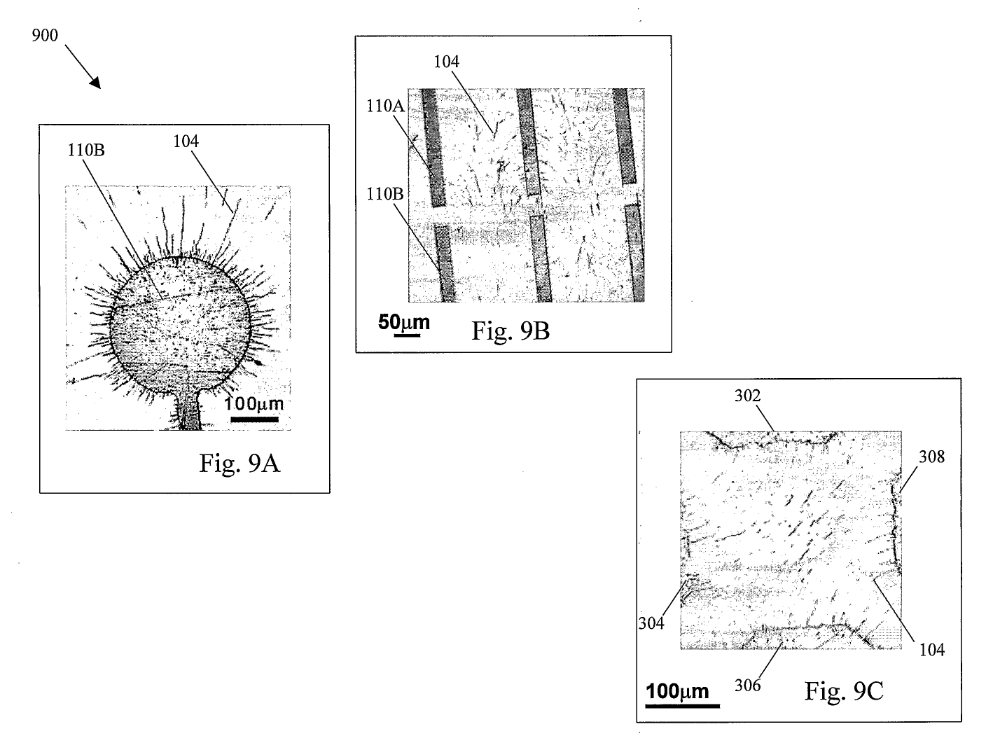

FIG. 8A depicts a nanostructure scaffold 800 in the form of a cross defined by square electrodes 802, 804, 806, 808. The center region 810 of the nanostructure scaffold 800, shown in detail in FIG. 8B, depicts nanostructures 104 (e.g., nanowires) in a square array. A distal region 810 of the nanostructure scaffold 800, shown in detail in FIG. 8C, depicts nanostructures 104 (e.g., nanowires) in a parallel array. Other example array shapes include radial arrays (FIG. 9A), circular patterns (FIG. 9B). A parallel array can be created using quadruple electrodes 302, 304, 306, 308, as depicted in FIG. 9C.

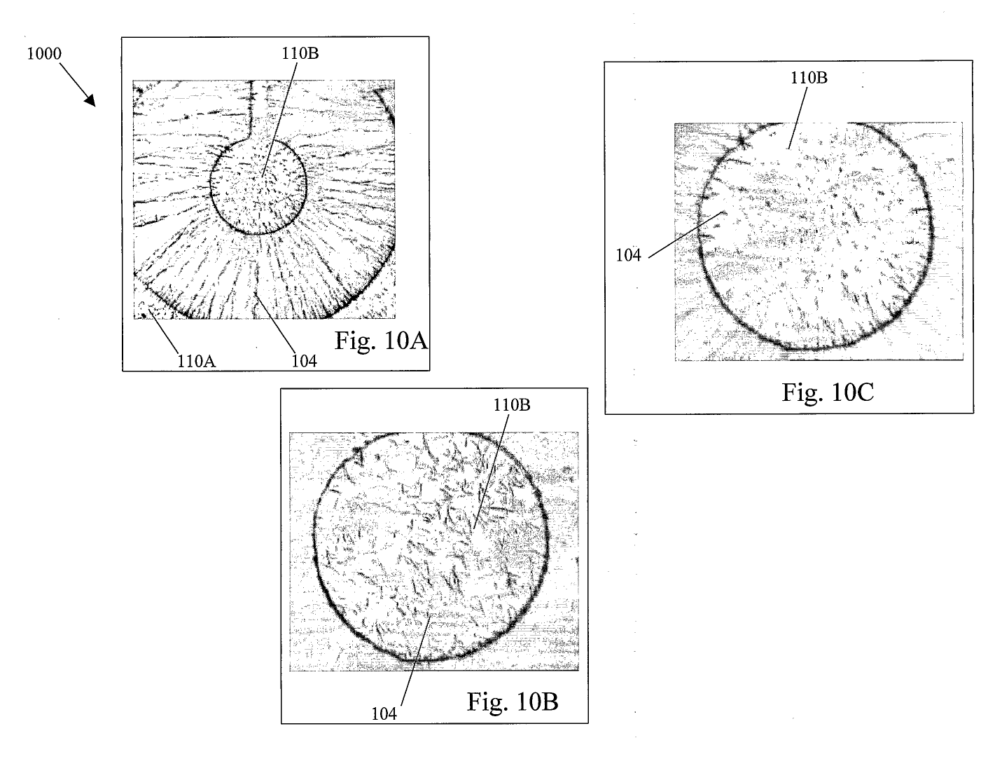

The nanostructure scaffolds described above are typically located in the space between the electrodes. Nevertheless, nanostructure scaffolds can also be constructed on top of the electrodes. As shown in FIG. 10A, nanostructures 104 (e.g., nanowires) are assembled and aligned in a radial manner between the electrodes 110A, 110B. On closer examination, FIG. 10B shows that the nanowires are also on top of the electrode 110B. After application of, for example, five volts at 10 MHz, the nanowires are aligned perpendicular to the electrode 110B, as depicted in FIG. 10.

From the foregoing, it will be appreciated that apparatus and methods according to the invention afford a simple and effective way to manipulate nanostructures.

One skilled in the art will realize the invention can be embodied in other specific forms without departing from the spirit or essential characteristics thereof. The foregoing embodiments are therefore to be considered in all respects illustrative rather than limiting of the invention described herein. Further, the phrase “at least one of” is intended to identify in the alternative all elements listed after that phrase, and does not require one of each element.

What is claimed is:

1. A system for transporting a nanostructure, comprising:
a substrate supporting the nanostructure;
a field generator;
a transport medium enveloping the nanostructure; and
a plurality of electrodes in contact with the transport medium and in communication with the field generator.

2. The system of claim 1, wherein the nanostructure comprises at least one of a nanosphere, a nanodisk, a nanowire, or a nanotube.

3. The system of claim 1, wherein the nanostructure is characterized at least in part by an aspect ratio.

4. The system of claim 3, wherein the aspect ratio is greater than one.

5. The system of claim 3, wherein the aspect ratio is greater than about 30.

6. The system of claim 1, wherein the field generator generates an electric field gradient.

7. The system of claim 1, wherein the transport medium is characterized at least in part by a Reynolds number.

8. The system of claim 7, wherein the Reynolds number is less than or equal to about 1×10⁻⁵.

9. The system of claim 1, wherein the transport medium comprises deionized water.

10. The system of claim 1, wherein the plurality of the electrodes comprises a circular electrode.

11. The system of claim 1, wherein the plurality of the electrodes comprises quadruple electrodes.

12. A system for rotating a nanostructure, comprising:
a substrate;
at least one nanostructure having at least one location capable of being attached to the substrate;
a transport medium enveloping the at least one nanostructure; and
a plurality of electrodes attached to the substrate and in contact with the transport medium for imposing an electric field and causing the at least one nanostructure to rotate.

13. The system of claim 12, wherein the substrate comprises quartz.

14. The system of claim 12, wherein the at least one nanostructure comprises at least one of at least one nanowire or at least one nanotube.

15-20. (canceled)

21. A nanostructure contact, comprising:
a substrate;
at least one nanostructure having at least one location capable of being attached to an adjacent member;
a transport medium enveloping the at least one nanostructure; and
a plurality of electrodes attached to the substrate and in contact with the transport medium for imposing an electric field gradient and causing the at least one nanostructure to be transported to and contact the adjacent member.

22. The nanostructure contact of claim 21, wherein the substrate comprises quartz.

23-28. (canceled)

29. A nanostructure scaffold, comprising:
a substrate;
a plurality of nanostructures;
a transport medium enveloping the nanostructures; and
a plurality of electrodes attached to the substrate and in contact with the transport medium for imposing an electric field gradient and causing the nanostructures to be transported to conform to a predetermined pattern.

30-34. (canceled)

35. A system for transporting a nanostructure, comprising:
means for supporting the nanostructure;
means for generating an electric field gradient;
means for enveloping the nanostructure; and
means for imposing the electric field gradient on the means for enveloping the nanostructure, thereby affecting the movement of the nanostructure.

36. The system of claim 35, wherein the nanostructure comprises at least one of a nanosphere, a nanodisk, a nanowire, or a nanotube.

37-44. (canceled)

45. A method of transporting a nanostructure, comprising:
supporting the nanostructure on a substrate;
enveloping the nanostructure with a transport medium;
generating an electric field gradient; and
imposing the electric field gradient on the transport medium, thereby affecting the transport of the nanostructure.

46-55. (canceled)
